(19) United States
(12) Patent Application Publication
(10) Pub. No.: US 2026/0304898 A1
(43) Pub. Date: Oct. 1, 2026

(54) DIAMOND SEMICONDUCTOR DEVICE AND METHOD FOR MANUFACTURING DIAMOND SEMICONDUCTOR DEVICE

(71) Applicant: Power Diamond Systems, Inc., Tokyo (JP)

(72) Inventors: Koji AMAZUTSUMI, Tokyo (JP); Tatsuya FUJISHIMA, Tokyo (JP); Hiroshi KAWARADA, Tokyo (JP)

(21) Appl. No.: 19/479,326

(22) PCT Filed: Nov. 20, 2024
(86) PCT No.: PCT/JP2024/041093

§ 371 Date: Oct. 27, 2025

(30) Foreign Application Priority Data
Nov. 22, 2023 (JP) 2023-198061

(51) Int. Cl. H10D 64/27; H10D 30/01; H10D 30/63; H10D 62/83; H10D 64/68

(52) U.S. Cl. CPC H10D 64/514; H10D 30/025; H10D 30/63; H10D 62/8303; H10D 64/518; H10D 64/683; H10D 64/691; H10D 64/693

(57) ABSTRACT

Provided is a diamond semiconductor device having a trench part on a front surface, comprising: a diamond layer; a diamond epitaxial layer provided on the diamond layer; a front-surface-side insulating film provided above the epitaxial layer; and a front-surface-side electrode provided on the front-surface-side insulating film, wherein the front-surface-side insulating film includes an embedded insulating part which is filled into an inside of the trench part to be in contact with a trench sidewall of the trench part.

### TECHNICAL FIELD

The present invention relates to a diamond semiconductor device and a method for manufacturing a diamond semiconductor device.

### BACKGROUND ART

Patent document 1 discloses a diamond semiconductor device comprising a trench structure.

### RELATED ART DOCUMENTS

### Patent Documents

Patent Document 1: Japanese Patent Application Publication No. 2017-092398

Reducing an on-resistance of a diamond semiconductor device is desirable.

### GENERAL DISCLOSURE

In the first aspect of the present invention, a diamond semiconductor device having a trench part on a front surface is provided. The diamond semiconductor device may comprise a diamond layer; a diamond epitaxial layer provided on the diamond layer; a front-surface-side insulating film provided above the epitaxial layer; and a front-surface-side electrode provided on the front-surface-side insulating film. The front-surface-side insulating film may include an embedded insulating part which is filled into an inside of the trench part to be in contact with a trench sidewall of the trench part.

In the second aspect of the present invention, a method for manufacturing a diamond semiconductor device having a trench part on a front surface is provided. The method for manufacturing a diamond semiconductor device may comprise: a step for providing a diamond layer; a step for forming a diamond epitaxial layer on the diamond layer; a step for forming a front-surface-side insulating film above the epitaxial layer; and a step for forming a front-surface-side electrode on the front-surface-side insulating film. The step for forming the front-surface-side insulating film may include a step for forming an embedded insulating part that is filled into an inside of the trench part to be in contact with a trench sidewall of the trench part.

The summary clause does not necessarily describe all necessary features of the embodiments of the present invention. In addition, the present invention may also be a sub-combination of the features described above.

### BRIEF DESCRIPTION OF THE DRAWINGS

FIG. 1A illustrates an example configuration of a diamond semiconductor device 100.

FIG. 1B illustrates a variant of the diamond semiconductor device 100.

FIG. 1C illustrates a variant of the diamond semiconductor device 100.

FIG. 1D illustrates a variant of the diamond semiconductor device 100.

FIG. 1E illustrates a variant of the diamond semiconductor device 100.

FIG. 1F illustrates a variant of the diamond semiconductor device 100.

FIG. 1G illustrates a variant of the diamond semiconductor device 100.

FIG. 2A illustrates an example of a method for manufacturing the diamond semiconductor device 100 of FIG. 1A.

FIG. 2B illustrates an example of a method for manufacturing the diamond semiconductor device 100 of FIG. 1A.

FIG. 2C illustrates an example of a method for manufacturing the diamond semiconductor device 100 of FIG. 1A.

FIG. 3A illustrates an example of a method for manufacturing the diamond semiconductor device 100.

FIG. 3B illustrates an example of a method for manufacturing the diamond semiconductor device 100.

FIG. 4A illustrates an example of a method for manufacturing the diamond semiconductor device 100.

FIG. 4B illustrates an example of a method for manufacturing the diamond semiconductor device 100.

FIG. 5 illustrates an example of a top view of the diamond semiconductor device 100.

FIG. 6A illustrates an example of a top view and a cross-sectional view of the diamond semiconductor device 100.

FIG. 6B illustrates an example of a top view of an integrated structure of the diamond semiconductor device 100.

FIG. 7A illustrates an example of a top view and a cross-sectional view of the diamond semiconductor device 100.

FIG. 7B illustrates an example of a top view of an integrated structure of the diamond semiconductor device 100.

FIG. 8 illustrates an overview of a configuration of a semiconductor module 200.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention.

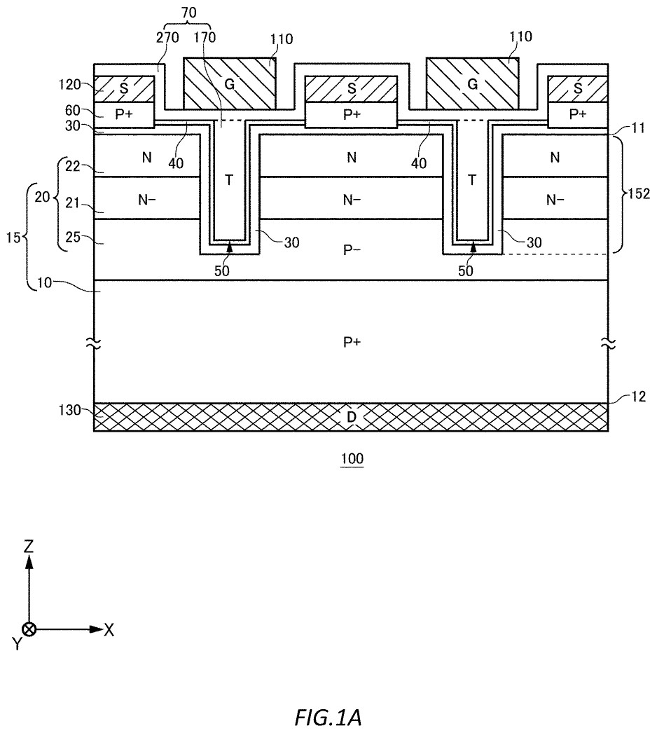

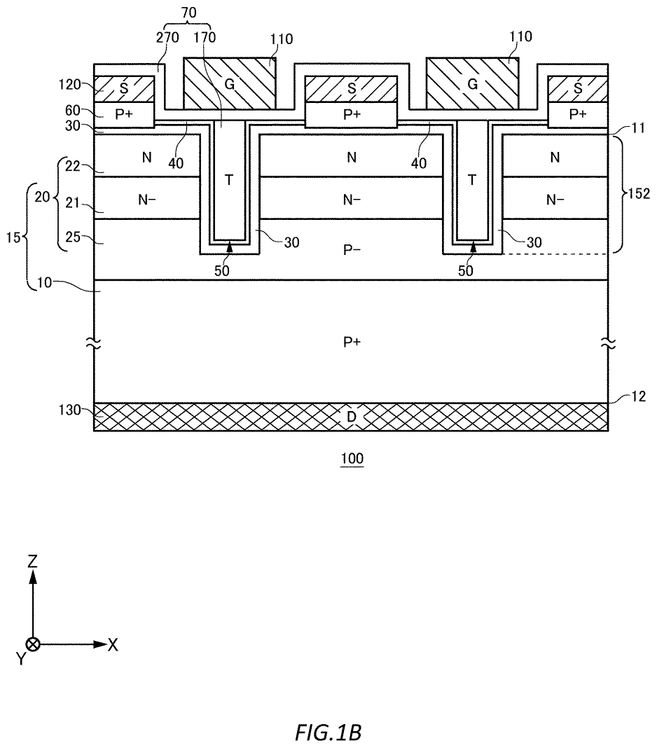

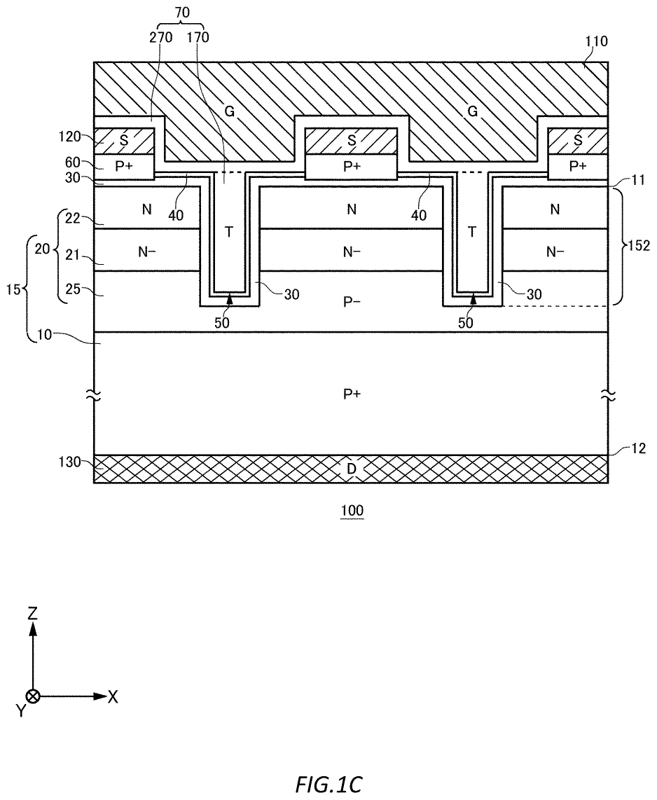

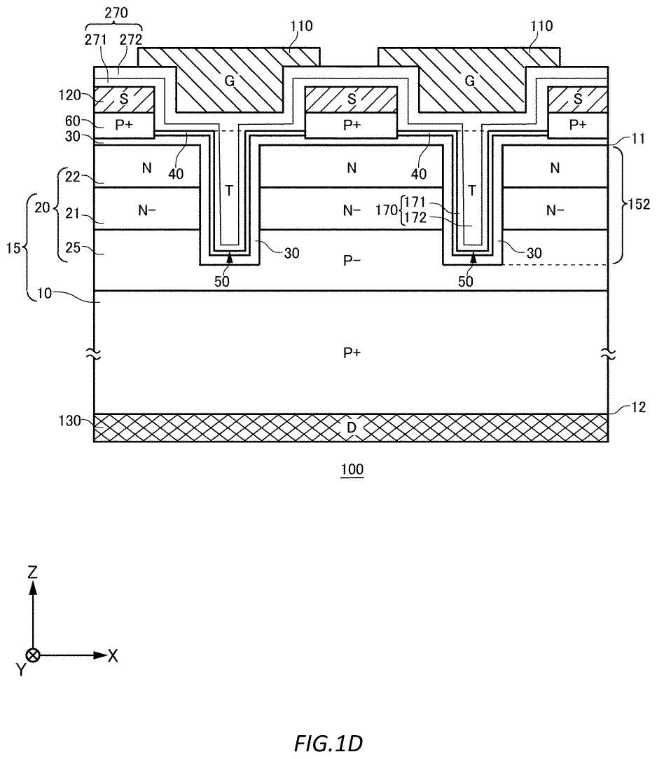

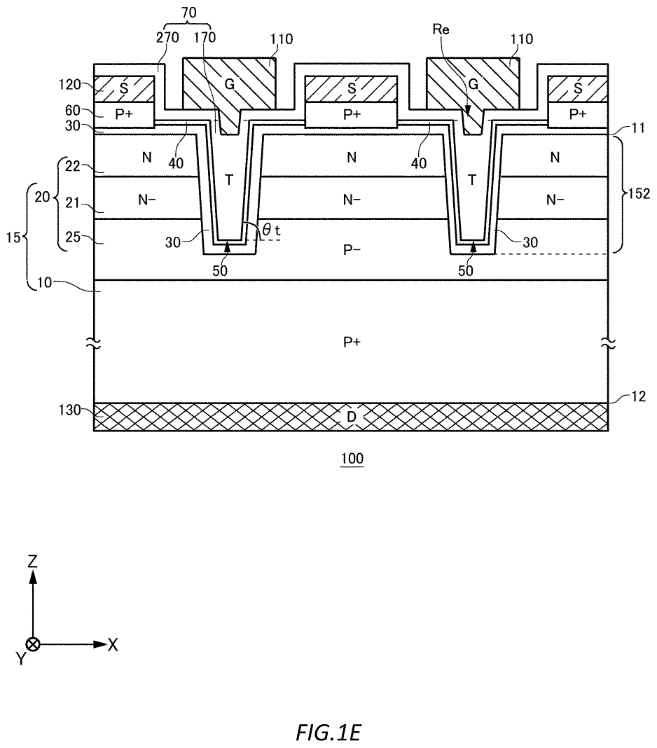

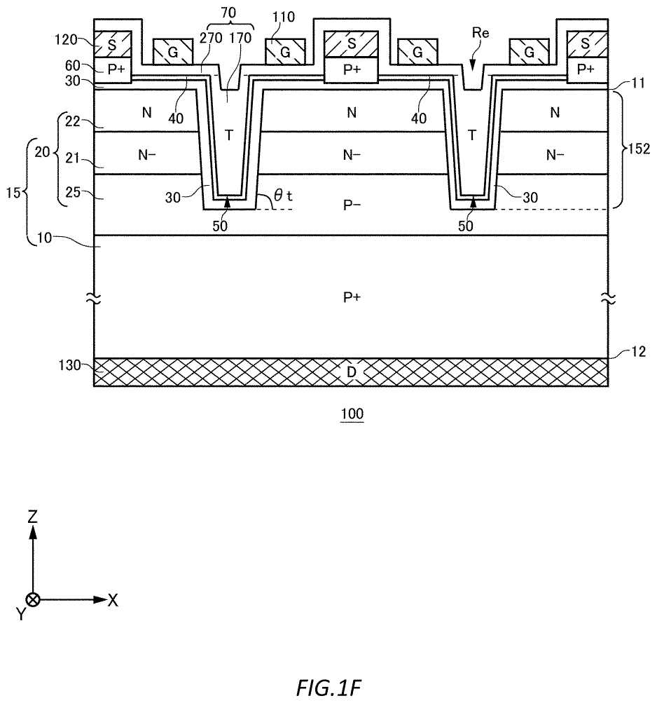

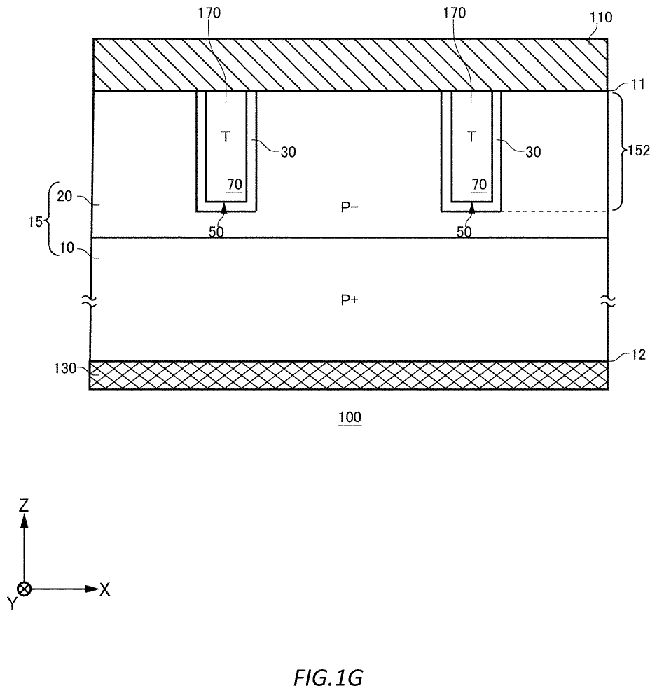

FIG. 1A illustrates an example of a configuration of a diamond semiconductor device 100. The diamond semiconductor device 100 of the present example is an example of a semiconductor device that functions as a metal-oxide-semiconductor field-effect transistor (MOSFET). The diamond semiconductor device 100 includes a diamond layer 15. The diamond layer 15 has a diamond substrate 10 and a doped region 20. The diamond layer 15 has the diamond substrate 10 on a back surface 12 side and has the doped region 20 on a front surface 11 side.

The diamond substrate 10 is a P-type substrate comprised of diamond. A doping concentration of a P-type dopant of the diamond substrate 10 may be 1×10¹⁹ cm⁻³ or more. The diamond substrate 10 may include the P-type dopant. In an example, the P-type dopant is a group III element, such as boron (B), aluminum (Al), gallium (Ga), or the like. The diamond substrate 10 of the present example is of a P+ type, but not limited thereto. The diamond semiconductor device 100 of the present example has a gate structure on the front surface 11 side.

Note that in the present specification, one side in a direction parallel to a depth direction of the diamond substrate 10 is referred to as “upper” and another side is referred to as “lower”. One surface of two principal surfaces of a substrate, a layer, or another member is referred to as an upper surface, and another surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described by using orthogonal coordinate axes of an X axis, a Y axis, and a Z axis. In the present specification, orthogonal axes parallel to an upper surface and a lower surface of the diamond substrate 10 are the X axis and the Y axis. Also, an axis vertical to the upper surface and the lower surface of the diamond substrate 10 is the Z axis. A Z-axis direction is a depth direction of the diamond substrate 10. In the present specification, a top view refers to a point of view seeing from a positive side to a negative side of the Z-axis direction.

In the present specification, a doping concentration of a dopant may be a concentration of a dopant that is introduced by intention. That is, a doping concentration of impurity left unintentionally may not be included in a doping concentration of a dopant. The dopant may be introduced during an epitaxial deposition, or may be implanted after a deposition.

The doped region 20 is provided above the diamond substrate 10. The doped region 20 of the present example includes an N-type dopant. The N-type dopant may be a group V element, such as nitrogen (N), phosphorus (P), arsenic (As), or antimony (Sb). The N-type dopant of the present example is nitrogen. A doping concentration of the N-type dopant of the doped region 20 may be 1×10¹⁵ cm⁻³ or more and 1×10²³ cm⁻³ or less.

The doped region 20 may be a region epitaxially deposited on the diamond substrate 10. The doped region 20 may be formed by Microwave Plasma Chemical Vapor Deposition (MPCVD). The N-type dopant may be introduced during the epitaxial deposition, or may be introduced in another method, such as ion implantation, after epitaxially depositing a non-doped diamond layer.

The doped region 20 of the present example has a first region 21 and a second region 22. A stacking structure of the doped region 20 can alleviate electric field concentration of the diamond semiconductor device 100. The doped region 20 may have a region including a P-type dopant. The doped region 20 of the present example has a P-type doped layer 25.

The doped layer 25 is provided above the diamond substrate 10. The doped layer 25 of the present example is provided to be in contact with the upper surface of the diamond substrate 10. The doped layer 25 of the present example includes the P-type dopant. The doped layer 25 of the present example is of P-type, but not limited thereto. A doping concentration of the P-type dopant of the doped layer 25 may be 1×10¹⁶ cm⁻³ or more and 1×10²¹ cm⁻³ or less. A thickness of the doped layer 25 may be thinner than a thickness of the diamond substrate 10. The thickness of the doped layer 25 may be thicker than a thickness of the first region 21, or may be thicker than a thickness of the second region 22.

The doped layer 25 is a P-type region in contact with an epitaxial layer 30. The doped layer 25 may be in contact with the epitaxial layer 30 provided on a sidewall of a trench part 50, or may be in contact with the epitaxial layer 30 provided on a bottom surface of the trench part 50. An upper end of the doped layer 25 may be provided above the bottom surface of the trench part 50. A lower end of the doped layer 25 may be provided below the bottom surface of the trench part 50.

The first region 21 is provided above the diamond substrate 10. The first region 21 of the present example is provided to be in contact with an upper surface of the doped layer 25. The first region 21 of the present example includes the N-type dopant. A doping concentration of the N-type dopant of first region 21 may be 1×10¹⁵ cm⁻³ or more and 1×10¹⁸ cm⁻³ or less. The thickness of the first region 21 may be thinner than the thickness of the diamond substrate 10, or may be thinner than the thickness of the doped layer 25. A doping concentration of the N-type dopant and the thickness of the first region 21 may be decided considering a breakdown voltage of the diamond semiconductor device 100.

The second region 22 is provided stacked with the first region 21. The second region 22 of the present example is provided above the first region 21. The second region 22 of the present example includes the N-type dopant. A doping concentration of the N-type dopant of the second region 22 is different from that of the first region 21. The doping concentration of the N-type dopant of the second region 22 of the present example is greater than the doping concentration of the N-type dopant of the first region 21. Note that the doping concentration of the N-type dopant of the second region 22 may be smaller than the doping concentration of the N-type dopant of the first region 21. The doping concentration of the N-type dopant of the second region 22 may be 1×10¹⁸ cm⁻³ or more and 1×10²¹ cm⁻³ or less. The doping concentration of the N-type dopant and the thickness of the second region 22 may be decided considering the breakdown voltage of the diamond semiconductor device 100. Also, a high doping concentration of the N-type dopant of the second region 22 facilitates suppressing leakage current in an OFF state.

The thickness of the second region 22 may be the same as, or may be different from the thickness of the first region 21. The thickness of the second region 22 may be thinner than the thickness of the first region 21. A thinner thickness of the second region 22 can lower the on-resistance while suppressing leakage current in the OFF state.

The epitaxial layer 30 is provided on the diamond layer 15. The epitaxial layer 30 of the present example is provided on the doped region 20, but may be provided on the diamond substrate 10. The epitaxial layer 30 is comprised of diamond. The epitaxial layer 30 may be formed after a concave part for providing the trench part 50 in the doped region 20 has been formed. The epitaxial layer 30 may be provided on the sidewall and the bottom surface of the concave part for providing the trench part 50. On the bottom surface of the concave part, the epitaxial layer 30 is in contact with the doped layer 25, but may be in contact with the diamond substrate 10. In the present specification, the concave part may be a dip formed by etching of the diamond layer 15. The sidewall and the bottom surface of the concave part may be comprised of the diamond layer 15.

The thickness of the epitaxial layer 30 may be 10 nm or more and less than 200 nm. The thickness of the epitaxial layer 30 may be 10 nm or more and 100 nm or less. The thickness of the epitaxial layer 30 may be 30 nm or more and 100 nm or less. A thinner thickness of the epitaxial layer 30 can shorten a distance that holes pass through the epitaxial layer 30 when the diamond semiconductor device 100 is in an ON state, to reduce the on-resistance.

The epitaxial layer 30 may include the N-type dopant. The N-type dopant may be nitrogen. A doping concentration of the N-type dopant of the epitaxial layer 30 may be smaller than that of the doped region 20. The doping concentration of the N-type dopant of the epitaxial layer 30 may be 1×10¹⁶ cm⁻³ or less. By reducing the doping concentration of the N-type dopant of the epitaxial layer 30, when holes from a termination layer 40 flow into and pass through the epitaxial layer 30 to flow into the doped layer 25 and then flow into the diamond substrate 10, a potential barrier in the epitaxial layer 30 can become smaller to reduce the on-resistance.

The epitaxial layer 30 may include the P-type dopant. A doping concentration of the P-type dopant of the epitaxial layer 30 may be set in a range that allows for turning on/off a gate. In an example, the doping concentration of the P-type dopant of the epitaxial layer 30 is 1×10¹⁵ cm⁻³ or more and 1×10¹⁹ cm⁻³ or less.

The termination layer 40 is provided on the epitaxial layer 30. The termination layer 40 of the present example is provided between the epitaxial layer 30 and a front-surface-side insulating film 70. The termination layer 40 may be a layer which induce 2 Dimensional Hole Gas (2DHG) in the epitaxial layer 30. To achieve a normally-off characteristic, the termination layer 40 may be a layer that has little conductivity when gate voltage is not applied. A thickness of the termination layer 40 may be 20 nm or less, and may be 0.1 nm or more.

The termination layer 40 may be a hydrogen-terminated layer, may be a silicon oxide-terminated layer, or may include both a hydrogen-terminated region and a silicon oxide-terminated region. The termination layer 40 may be hydrogen-terminated by irradiating with hydrogen radicals, or may be silicon oxide-terminated by a reduction reaction in a high-temperature atmosphere of silicon dioxide and diamond.

The termination layer 40 may include at least one of C—H bond, C—O bond, C—Si bond, C—Si—O bond, C—F bond, C—OH bond, C—N bond, or C—NH₂ bond. The termination layer 40 may have a same kind of bond for its entire region of the termination layer 40, or may have a different kind of bond for each region. The termination layer 40 may have a same kind of bond on its entire surface between the epitaxial layer 30 and a front-surface-side insulating film 70. The termination layer 40 may have C—H bonds on its entire surface between the epitaxial layer 30 and the front-surface-side insulating film 70.

The front-surface-side insulating film 70 is provided above the epitaxial layer 30. The front-surface-side insulating film 70 is provided on the front surface 11 side of the diamond layer 15. The front-surface-side insulating film 70 may be provided above the epitaxial layer 30, or may be provided on the termination layer 40. In the gate trench part 50, the front-surface-side insulating film 70 may be provided on the sidewall and the bottom surface of the trench. A thickness of the front-surface-side insulating film 70 may be 50 nm or more and may be 200 nm or less. The thickness of the front-surface-side insulating film 70 may be 50 nm or more and 100 nm or less. The thickness of the front-surface-side insulating film 70 is 100 nm, for example.

The front-surface-side insulating film 70 may include at least one of aluminum oxide (Al₂O₃), silicon oxide (SiO₂), silicon nitride (SiNx), hafnium oxide (HfO₂), hafnium silicate (HfSiO₄), or boron nitride (BN). The composition of Al₂O₃ may not necessarily be Al:O=2:3. The front-surface-side insulating film 70 may be a single layer, or may have a stacking structure that stacks different materials. The front-surface-side insulating film 70 of the present example is a single-layered Al₂O₃ formed by Atomic Layer Deposition (ALD).

The front-surface-side insulating film 70 of the present example has an embedded insulating part 170 and a non-embedded insulating part 270. Note that the non-embedded insulating part 270 may be omitted.

The embedded insulating part 170 is filled into an inside of the trench part 50 and in contact with a trench sidewall of the trench part 50. The embedded insulating part 170 may fill all of, or may fill a part of the inside of the trench of the trench part 50. The embedded insulating part 170 may fill 50% or more, or may fill 75% or more, or may fill 90% or more of the inside of the trench of the trench part 50.

The non-embedded insulating part 270 is provided above a mesa part 152 adjacent to the trench part 50. The non-embedded insulating part 270 may be provided above a contact region 60 and may be provided above a source electrode 120.

The embedded insulating part 170 and the non-embedded insulating part 270 may be deposited in a same process, or may be deposited in different processes. The embedded insulating part 170 and the non-embedded insulating part 270 of the present example are simultaneously deposited in a same process. When the embedded insulating part 170 and the non-embedded insulating part 270 are simultaneously deposited, the embedded insulating part 170 and the non-embedded insulating part 270 may be integrated. When the embedded insulating part 170 and the non-embedded insulating part 270 are simultaneously deposited, a region inside the trench of the trench part 50 becomes the embedded insulating part 170, and a region provided above the mesa part 152 becomes the non-embedded insulating part 270.

A material of the embedded insulating part 170 may be the same as, or may be different from a material of the non-embedded insulating part 270. The material of the embedded insulating part 170 of the present example is the same as that of the non-embedded insulating part 270. For example, the material of the embedded insulating part 170 and the non-embedded insulating part 270 is Al₂O₃. Electrons would be trapped if there is a dangling bond on a surface of the epitaxial layer 30, but by Al₂O₃ bonding with the dangling bond, electron trapping can be suppressed, thereby improving the electrical conductivity of the termination layer 40.

The material of the embedded insulating part 170 includes at least one of SiO₂, SiNx, HfO₂, HfSiO₄, or BN, and the material of the non-embedded insulating part 270 may include at least one of Al₂O₃, SiO₂, SiNx, HfO₂, HfSiO₄, or BN. Also, the material of the embedded insulating part 170 includes at least one of Al₂O₃, SiO₂, SiNx, HfO₂, HfSiO₄, or BN, and the material of the non-embedded insulating part 270 may include at least one of SiO₂, SiNx, HfO₂, HfSiO₄, or BN.

The trench part 50 is provided to extend in a depth direction of the diamond layer 15. The trench part 50 includes the front-surface-side insulating film 70 provided in the trench. The trench part 50 may be comprised of the front-surface-side insulating film 70 only. The trench part 50 of the present example does not include the epitaxial layer 30 or the termination layer 40. The trench part 50 may be in contact with the termination layer 40 on the sidewall and the bottom surface. A lower end of the trench part 50 may be located deeper than the upper end of the doped layer 25. That is, the trench part 50 may extend to inside the doped layer 25. The lower end of the trench part 50 may be located deeper than the upper end of the diamond substrate 10. Reference sign T represent a region of the trench part 50.

A trench width of the trench part 50 may be 100 nm or more and 1.5 μm or less. The trench width of the trench part 50 may be a width of the trench part 50 at an upper end of the trench part 50. The upper end of the trench part 50 is an upper end of the embedded insulating part 170. The upper end of the trench part 50 may be at a same height as an upper end of the termination layer 40. A depth of the trench may be 60 nm or more and 20 μm or less. An aspect ratio of the trench part 50 may be two or more and five or less.

The contact region 60 is provided above the epitaxial layer 30. The contact region 60 may be provided in contact with the source electrode 120. The contact region 60 may include the P-type dopant. The contact region 60 of the present example is of P+ type, but not limited thereto. A doping concentration of the contact region 60 of the present example may be the same as, or may be different from the doping concentration of the diamond substrate 10. The doping concentration of the contact region 60 may be greater than, or may be smaller than the doping concentration of the diamond substrate 10. The P-type dopant may be a group III element, such as boron (B), aluminum (Al), or gallium (Ga). The P-type dopant may be introduced during the epitaxial deposition, or may be introduced in another method, such as ion implantation, after epitaxially depositing a non-doped diamond layer. The thickness of the contact region 60 may be thicker than the thickness of the epitaxial layer 30. The thickness of the contact region 60 may be thinner than the thickness of the epitaxial layer 30.

A front-surface-side electrode 110 is provided above the diamond layer 15. The front-surface-side electrode 110 of the present example is provided on the front-surface-side insulating film 70. The front-surface-side electrode 110 may function as a gate electrode, and the front-surface-side insulating film 70 may function as a gate insulating film. The front-surface-side electrode 110 of the present example is located above the front surface 11, and is not provided inside the trench of the trench part 50. The front-surface-side electrode 110 of the present example is provided above the trench part 50 and the mesa part 152. The front-surface-side electrode 110 may be provided, in a top view, in a region inward of a region where the front-surface-side insulating film 70 is provided. That is, the front-surface-side electrode 110 may be provided to overlap the front-surface-side insulating film 70 in a top view. The front-surface-side electrode 110 may have any electrode material, such as aluminum (Al). Reference sign G represents a region of the front-surface-side electrode 110, i.e., the gate electrode.

The front-surface-side electrode 110 may be provided to extend from above one sidewall of the trench part 50 to above another sidewall, covering over the embedded insulating part 170. The front-surface-side electrode 110 may be provided to cover the entire surface of the upper surface of the trench part 50, or may be provided to cover a part of the upper surface of the trench part 50. The front-surface-side electrode 110 may be provided to extend from above one sidewall of the trench part 50, but not reach above another sidewall and terminate, not entirely covering over the embedded insulating part 170.

The source electrode 120 is provided above the diamond layer 15. The source electrode 120 may be provided on the front surface 11 side of the diamond layer 15. The source electrode 120 may be provided on the contact region 60. The source electrode 120 may be provided, in a top view, in a same region as the contact region 60, or may be provided inside the contact region 60. The source electrode 120 may be a stacked film that stacks titanium (Ti) and gold (Au). The source electrode 120 may be a stacked film that stacks titanium (Ti), platinum (Pt), and gold (Au). A source voltage may be applied to the source electrode 120 provided on the front surface 11 side of the diamond layer 15. Reference sign S represents a region of the source electrode 120.

A back-surface-side electrode 130 is provided to be in contact with the diamond substrate 10. The back-surface-side electrode 130 of the present example functions as a drain electrode. The back-surface-side electrode 130 is provided on the back surface 12 side of the diamond layer 15. The back-surface-side electrode 130 may be provided on the entire surface of the back surface 12, or may be provided on a part of the back surface 12. The back-surface-side electrode 130 may be a stacked film that stacks titanium (Ti) and gold (Au). The back-surface-side electrode 130 may be a stacked film that stacks titanium (Ti), platinum (Pt), and gold (Au). The back-surface-side electrode 130 is provided to be in contact with the back surface 12 of the diamond substrate 10. A drain-source voltage may be applied to the back-surface-side electrode 130 provided on the back surface 12 side of the diamond layer 15. Reference sign D represents a region of the back-surface-side electrode 130, i.e., the drain electrode.

The diamond semiconductor device 100 of the present example includes the front-surface-side electrode 110 and the source electrode 120 on the front surface 11 side of the diamond layer 15, and includes the back-surface-side electrode 130 on the back surface 12 side of the diamond layer 15. When the diamond semiconductor device 100 is turned ON, current flows from the source electrode 120 to the contact region 60, then to the termination layer 40, and holes pass through the epitaxial layer 30 to move into the diamond substrate 10, causing current to flow through the back-surface-side electrode 130.

Note that in the present example, a case is described where the diamond semiconductor device 100 is a P-type channel field effect transistor, but the diamond semiconductor device 100 may be an N-type channel field effect transistor. When the diamond semiconductor device 100 functions as an N-type channel field effect transistor, the P-type dopant may be replaced with the N-type dopant, and the N-type dopant may be replaced with the P-type dopant.

FIG. 1B illustrates a variant of the diamond semiconductor device 100. The diamond semiconductor device 100 of the present example is different from the diamond semiconductor device 100 in FIG. 1A in that the embedded insulating part 170 and the non-embedded insulating part 270 are formed of different materials. In the present example, differences from the diamond semiconductor device 100 in FIG. 1A will be mainly described.

A dielectric constant of the embedded insulating part 170 may be lower than a dielectric constant of the non-embedded insulating part 270. A lower dielectric constant of the embedded insulating part 170 facilitates to improve the breakdown voltage of the diamond semiconductor device 100. In an example, the material of the embedded insulating part 170 includes at least one of SiO₂, SiNx, or BN, and the material of the non-embedded insulating part 270 includes at least one of Al₂O₃, HfO₂, or HfSiO₄.

The non-embedded insulating part 270 may be formed using a method having a quicker deposition speed with respect to the embedded insulating part 170. The non-embedded insulating part 270 may be deposited using CVD. In an example, the material of the embedded insulating part 170 includes at least one of HfO₂, HfSiO₄, or BN, and the material of the non-embedded insulating part 270 may include at least one of Al₂O₃, SiO₂, or SiNx.

The embedded insulating part 170 may be Al₂O₃ formed by ALD. When forming SiO₂ or the like by CVD or the like, deposition speed can be quicker with respect to forming Al₂O₃ by ALD. For example when a resistivity of the trench sidewall becomes dominant due to miniaturization of the diamond semiconductor device 100, forming the embedded insulating part 170 with Al₂O₃ can lower a resistivity of the termination layer 40 at the trench sidewall.

FIG. 1C illustrates a variant of the diamond semiconductor device 100. The diamond semiconductor device 100 of the present example is different from the diamond semiconductor device 100 in FIG. 1A in where to provide the front-surface-side electrode 110. In the present example, differences from the diamond semiconductor device 100 in FIG. 1A will be mainly described.

The front-surface-side electrode 110 is provided to cover over both the trench part 50 and the mesa part 152. The front-surface-side electrode 110 may be provided to entirely cover the source electrode 120 at the mesa part 152 between two adjacent trench parts 50. The front-surface-side electrode 110 may be provided to extend from above one sidewall of the trench part 50 to above another sidewall, covering over the trench part 50.

The diamond semiconductor device 100 of the present example facilitates forming the front-surface-side electrode 110 even when the trench structure and the source electrode 120 are miniaturized. The diamond semiconductor device 100 of the present example includes the embedded insulating part 170 and the non-embedded insulating part 270 of a same material, but may include the embedded insulating part 170 and the non-embedded insulating part 270 of different materials. A structure of the front-surface-side electrode 110 of the present example may be applied as appropriate to a front-surface-side electrode 110 of another embodiment.

FIG. 1D illustrates a variant of the diamond semiconductor device 100. The diamond semiconductor device 100 of the present example is different from the diamond semiconductor device 100 in FIG. 1A in including a multi-layered front-surface-side insulating film 70. In the present example, differences from the diamond semiconductor device 100 in FIG. 1A will be mainly described.

The embedded insulating part 170 of the present example has a bilayered structure of a first embedded insulating film 171 and a second embedded insulating film 172. The non-embedded insulating part 270 of the present example has a bilayered structure of a first non-embedded insulating film 271 and a second non-embedded insulating film 272. The first embedded insulating film 171 may be formed simultaneously with the first non-embedded insulating film 271. The second embedded insulating film 172 may be formed simultaneously with the second non-embedded insulating film 272.

The first embedded insulating film 171 is provided to be in contact with the trench sidewall of the trench part 50. That is, the first embedded insulating film 171 is provided to be in contact with the termination layer 40 on the trench sidewall. The first embedded insulating film 171 may be provided to be in contact with the epitaxial layer 30 if the termination layer 40 does not exist.

The second embedded insulating film 172 is provided to be stacked with the first embedded insulating film 171 at the trench part 50. That is, the second embedded insulating film 172 is provided inside the first embedded insulating film 171 at the trench part 50. The second embedded insulating film 172 may fully fill inside the first embedded insulating film 171 at the trench part 50. A material of the second embedded insulating film 172 may be the same as, or may be different from a material of the embedded insulating part 170.

A thickness of the first embedded insulating film 171 may be thinner than that of the second embedded insulating film 172. The first embedded insulating film 171 may have any thickness in view of improving its characteristics at an interface of the first embedded insulating film 171 and the epitaxial layer 30, as will be described below. The thickness of the first embedded insulating film 171 may be 10 nm or more and 100 nm or less. The second embedded insulating film 172 may be deposited using a method having a quicker deposition speed with respect to the first embedded insulating film 171. This facilitates shortening a deposition time period required to deposit the front-surface-side insulating film 70. In an example, the first embedded insulating film 171 is deposited by ALD, and the second embedded insulating film 172 is deposited by CVD.

The non-embedded insulating part 270 may be provided above the trench part 50, may be provided above the mesa part 152, or may be provided above the source electrode 120.

The first non-embedded insulating film 271 may be provided on the upper surface of the trench part 50, may be provided on the upper surface of the termination layer 40, or may be provided on the upper surface of the source electrode 120. The second non-embedded insulating film 272 is provided to be stacked with the first non-embedded insulating film 271. A thickness of the second non-embedded insulating film 272 may be the same as, or may be different from a thickness of the first non-embedded insulating film 271. The thickness of the second non-embedded insulating film 272 may be thicker than the thickness of the first non-embedded insulating film 271. The second non-embedded insulating film 272 may be deposited using a method having a quicker deposition speed with respect to the first non-embedded insulating film 271.

The thickness of the first non-embedded insulating film 271 may be the same as, or may be different from the thickness of the first embedded insulating film 171 inside the trench. The thickness of the first non-embedded insulating film 271 may be 10 nm or more and 100 nm or less, as with the first embedded insulating film 171. A deposition method of the first non-embedded insulating film 271 of the present example is the same as the deposition method of the first embedded insulating film 171, but may be different from it.

The thickness of the second non-embedded insulating film 272 may be the same as, or may be different from the thickness of the second embedded insulating film 172 inside the trench. A deposition method of the second non-embedded insulating film 272 of the present example is the same as the deposition method of the second embedded insulating film 172, but may be different from it.

The front-surface-side electrode 110 is provided above the non-embedded insulating part 270 above the mesa part 152. The front-surface-side electrode 110 of the present example is provided on the second non-embedded insulating film 272. The front-surface-side electrode 110 may be provided above the source electrode 120. The front-surface-side electrode 110 of the present example is provided so that at least a part of it overlaps the source electrode 120. Providing the front-surface-side electrode 110 above the source electrode 120 as well allows for arranging the front-surface-side electrode 110 and the source electrode 120 to overlap with each other, thereby facilitating miniaturization.

FIG. 1E illustrates a variant of the diamond semiconductor device 100. The diamond semiconductor device 100 of the present example is different from the diamond semiconductor device 100 in FIG. 1A in that the trench part 50 has a taper. In the present example, differences from the diamond semiconductor device 100 in FIG. 1A will be mainly described.

The trench part 50 has a taper and has a predetermined tapering angle θt. The trench part 50 may have a forward taper, i.e., have a tapering angle θt greater than zero degrees and less than 90 degrees, or may have a reverse taper, i.e., have a tapering angle θt greater than 90 degrees and less than 180 degrees. The trench part 50 of the present example has a forward taper. Because the trench part 50 has the tapering angle θt, an embedding condition of the front-surface-side insulating film 70 changes, and the geometry of a dip Re in the front-surface-side insulating film 70 changes.

When the embedding condition changes depending on the tapering angle θt, a penetration depth of the front-surface-side electrode 110 into the trench part 50 changes. By changing the penetration depth of the front-surface-side electrode 110, a gate control region, where the front-surface-side electrode 110 and the front-surface-side insulating film 70 come in contact and the front-surface-side electrode 110 functions as a gate, can be adjusted. Also, by changing the penetration depth of the front-surface-side electrode 110, the breakdown voltage of the diamond semiconductor device 100 can be adjusted. For example, by adjusting the penetration depth of the front-surface-side electrode 110, a drop in the breakdown voltage can be suppressed. The tapering angle θt may be 60 degrees or more and 100 degrees or less.

A tapered structure of the trench part 50 of the present example may be applied to a diamond semiconductor device 100 of another embodiment as appropriate. The front-surface-side insulating film 70 of the present example has the embedded insulating part 170 and the non-embedded insulating part 270 having a single-layered structure, but may have the embedded insulating part 170 and the non-embedded insulating part 270 having a stacking structure. A material of the embedded insulating part 170 of the present example is the same as a material of the non-embedded insulating part 270, but may be different from it. For the diamond semiconductor device 100, by changing the tapering angle θt and a method of forming the front-surface-side insulating film 70, the geometry of the dip Re can be changed to adjust the penetration depth of the front-surface-side electrode 110.

FIG. 1F illustrates a variant of the diamond semiconductor device 100. The diamond semiconductor device 100 of the present example is different from the diamond semiconductor device 100 in FIG. 1E in where to provide the front-surface-side electrode 110. In the present example, differences from the diamond semiconductor device 100 in FIG. 1E will be mainly described.

The front-surface-side electrode 110 is not provided above the trench part 50, but provided above the mesa part 152 adjacent to the trench part 50. The front-surface-side electrode 110 may be provided above the mesa part 152 at each end of the trench part 50. The front-surface-side electrode 110 of the present example is provided not to overlap the source electrode 120 in a top view, but may be provided to overlap the source electrode 120.

The front-surface-side electrode 110 of the present example is not provided above the trench part 50, so it is possible to avoid filling the dip Re of the front-surface-side insulating film 70 with the front-surface-side electrode 110. When the front-surface-side insulating film 70 of the trench part 50 has the dip Re and the front-surface-side electrode 110 is provided in the dip Re, a distance between the diamond substrate 10 and the front-surface-side electrode 110 may be shortened to cause a drop in the breakdown voltage. In the diamond semiconductor device 100 of the present example, the front-surface-side electrode 110 is provided to be spaced apart from the dip Re, to facilitate suppressing a drop in the breakdown voltage. The front-surface-side electrode 110 of the present example is arranged not to overlap the source electrode 120, but may be arranged to overlap the source electrode 120.

FIG. 1G illustrates a variant of the diamond semiconductor device 100. The diamond semiconductor device 100 of the present example includes a diode structure. The diamond semiconductor device 100 of the present example includes a diamond layer 15, an epitaxial layer 30, a trench part 50, a front-surface-side electrode 110, and a back-surface-side electrode 130. The front-surface-side electrode 110 may function as a cathode. The back-surface-side electrode 130 may function as an anode.

A diamond substrate 10 is a P+ type substrate comprised of diamond. The diamond substrate 10 may have a same dopant and doping concentration as described in the embodiment where the diamond semiconductor device 100 functions as a MOSFET.

The doped region 20 is provided on the diamond substrate 10. The doped region 20 includes the P-type dopant. The doped region 20 of the present example is of P-type, but not limited thereto.

The epitaxial layer 30 may include the N-type dopant. The epitaxial layer 30 may be of N+ type. There may be provided a termination layer 40 between the epitaxial layer 30 and a front-surface-side insulating film 70. The termination layer 40 between the epitaxial layer 30 and the front-surface-side insulating film 70 may be of N+ type.

The trench part 50 has the front-surface-side insulating film 70. The front-surface-side insulating film 70 is filled in a trench of the trench part 50. That is, the front-surface-side insulating film 70 of the present example has an embedded insulating part 170. The front-surface-side insulating film 70 may have a plurality of insulating films in the trench part 50. The front-surface-side insulating film 70 may stack a plurality of films of different kinds, or may stack films of a same kind.

The front-surface-side insulating film 70 of the present example is not provided on the mesa part 152. That is, the front-surface-side insulating film 70 may not have a non-embedded insulating part 270.

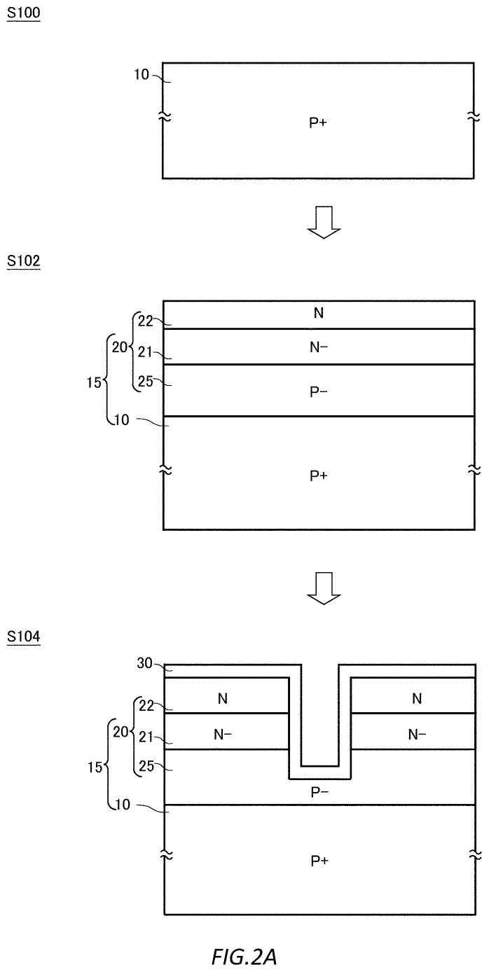

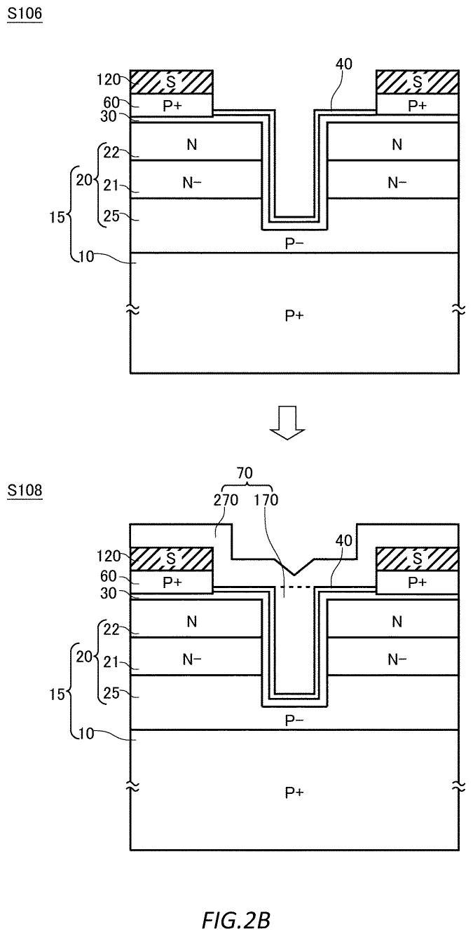

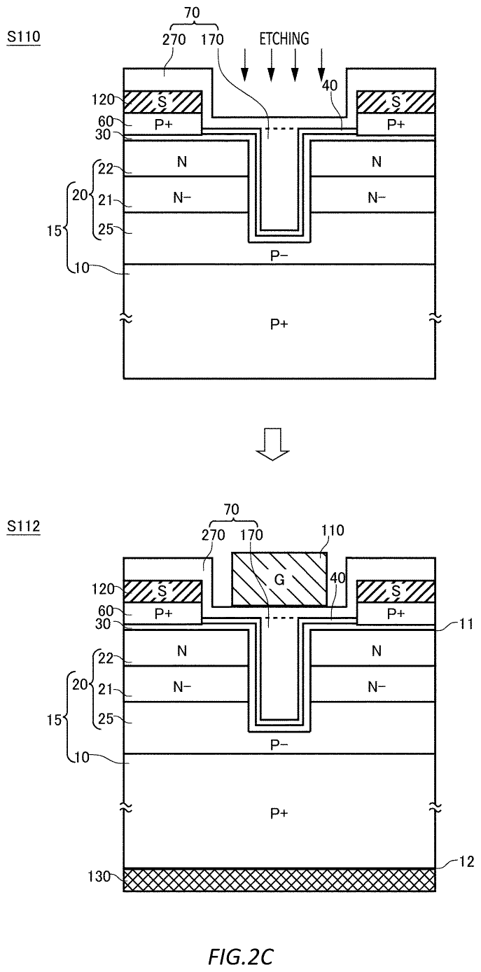

FIG. 2A illustrates an example of a method for manufacturing the diamond semiconductor device 100 of FIG. 1A. In Step S100, the P-type diamond substrate 10 is prepared.

In Step S102, the doped region 20 that includes the N-type dopant is formed above the diamond substrate 10. In the present example, the doped region 20 is formed by epitaxially depositing on the diamond substrate 10. The doped layer 25 of the present example is formed by introducing the P-type dopant during the epitaxial deposition. The first region 21 and the second region 22 of the present example are formed by introducing the N-type dopant during the epitaxial deposition. The first region 21 and the second region 22 may be formed by epitaxially depositing them in succession after epitaxially depositing the doped layer 25. The first region 21 and the second region 22 may have different doping concentrations by changing an amount of the N-type dopant during the epitaxial deposition.

In Step S104, a concave part is formed by etching the diamond layer 15. In the present example, the concave part is formed by etching the second region 22, the first region 21, and the doped layer 25. After forming the concave part, the epitaxial layer 30 is formed. The epitaxial layer 30 may be formed on the sidewall and the bottom surface of the concave part, or may be formed on the upper surface of the second region 22. The epitaxial layer 30 may be formed by epitaxially depositing it on the diamond layer 15.

FIG. 2B illustrates an example of a method for manufacturing the diamond semiconductor device 100 of FIG. 1A. The present illustration shows the subsequent processes of Step S104 in FIG. 2A.

In Step S106, the contact region 60 and the source electrode 120 are formed on the epitaxial layer 30. The contact region 60 may be formed by epitaxially depositing it on the epitaxial layer 30. The contact region 60 may be of P+ type. The contact region 60 may be omitted. In Step S106, the termination layer 40 may be formed. The termination layer 40 may be formed after forming the source electrode 120. The termination layer 40 may be formed on the epitaxial layer 30 by introducing any gas during annealing. The termination layer 40 may be formed by hydrogen-terminating the epitaxial layer 30, or may be formed by silicon oxide-terminating the epitaxial layer 30.

In Step S108, the front-surface-side insulating film 70 is formed. The front-surface-side insulating film 70 is formed above the epitaxial layer 30. The front-surface-side insulating film 70 of the present example is formed above the termination layer 40. The front-surface-side insulating film 70 may be formed using a method like ALD, or CVD. The step for forming the front-surface-side insulating film 70 includes a step for forming the embedded insulating part 170 that is filled into an inside of the trench part 50 to be in contact with the trench sidewall of the trench part 50. The step for forming the front-surface-side insulating film 70 may include a step for forming the non-embedded insulating part 270 outside the trench part 50. After forming the front-surface-side insulating film 70, an interface between the termination layer 40 and the front-surface-side insulating film 70 may be improved by annealing or the like.

In the present example, the termination layer 40 is formed on the epitaxial layer 30 before forming the front-surface-side insulating film 70. Note that the termination layer 40 between the front-surface-side insulating film 70 and the epitaxial layer 30 may be formed after forming the front-surface-side insulating film 70 on the epitaxial layer 30.

FIG. 2C illustrates an example of a method for manufacturing the diamond semiconductor device 100 of FIG. 1A. The present illustration shows the subsequent processes of Step S108 in FIG. 2B.

In Step S110, the front-surface-side insulating film 70 is etched. In the present example, only the non-embedded insulating part 270 outside the trench among the front-surface-side insulating film 70 is etched, but the embedded insulating part 170 inside the trench may be etched as well. The front-surface-side insulating film 70 may be etched to a thickness with which the gate is controllable via the front-surface-side electrode 110. An entire surface of the front-surface-side insulating film 70 may be etched, or only a region of the front-surface-side insulating film 70 in which the front-surface-side electrode 110 is formed may be etched. The etching process of the front-surface-side insulating film 70 may be omitted.

In Step S112, the front-surface-side electrode 110 is formed on the front-surface-side insulating film 70. The front-surface-side electrode 110 may be formed above the front-surface-side insulating film 70 which has been etched. The back-surface-side electrode 130 may be formed on the back surface 12 of the diamond substrate 10.

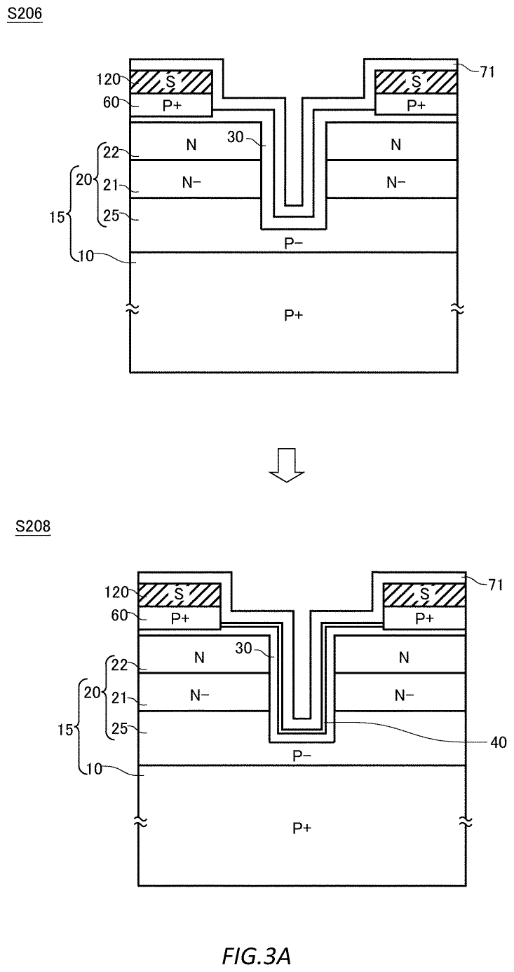

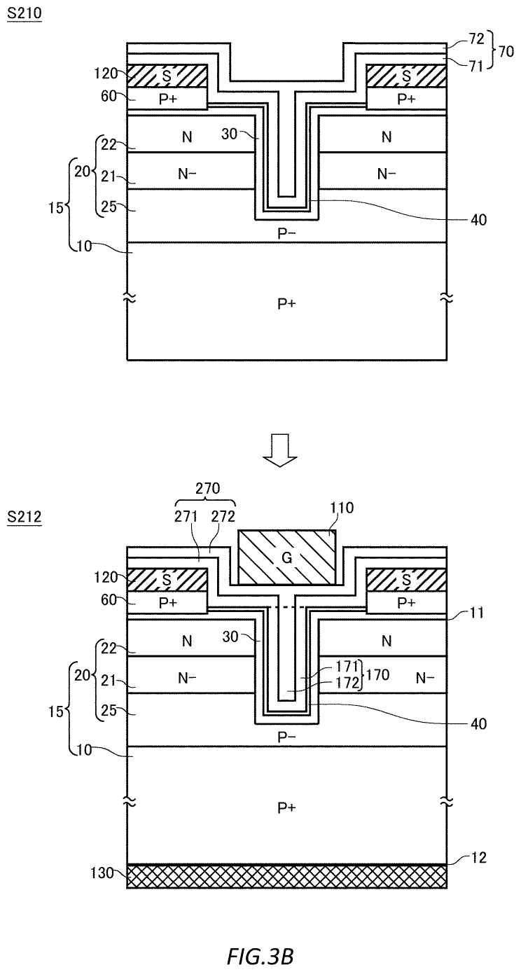

FIG. 3A illustrates an example of a method for manufacturing the diamond semiconductor device 100. In the present example, the description begins with a formation process of the front-surface-side insulating film 70. Formation processes up to the source electrode 120 may be the same as those of other manufacturing methods. The front-surface-side insulating film 70 of the present example may be formed by stacking the first insulating film 71 and the second insulating film 72.

In Step S206, the first insulating film 71 may be formed above the epitaxial layer 30. The first insulating film 71 may not embed the trench entirely, but leave a part of it hollow. In the present example, the first insulating film 71 is formed to be in contact with the trench sidewall of the trench part 50. Thereby, the first embedded insulating film 171 is provided to be in contact with the trench sidewall of the trench part 50.

In Step S208, the termination layer 40 is formed by annealing the diamond semiconductor device 100. In the present example, the diamond semiconductor device 100 is annealed after a step for forming the first embedded insulating film 171 and before a step for forming the second embedded insulating film 172. The step for forming the first embedded insulating film 171 may be a step for forming the first insulating film 71 to form the first embedded insulating film 171. The step for forming the second embedded insulating film 172 may be a step for forming the second insulating film 72 to form the second embedded insulating film 172. Since the inside of the trench is not entirely embedded with the first insulating film 71 when annealed and gas is also supplied inside the trench, quality of an interface of the termination layer 40 is improved. The diamond semiconductor device 100 may be annealed in a nitrogen atmosphere, or may be annealed in a hydrogen atmosphere. The interface between the termination layer 40 and the first insulating film 71 may be improved by annealing the diamond semiconductor device 100, for example.

Note that in the present example, the termination layer 40 is formed after the step for forming the first embedded insulating film 171 and before the step for forming the second embedded insulating film 172, but the termination layer 40 may be formed before the step for forming the first embedded insulating film 171. Also, the termination layer 40 may be formed after forming the first embedded insulating film 171 and the second embedded insulating film 172.

FIG. 3B illustrates an example of a method for manufacturing the diamond semiconductor device 100. The present illustration shows the subsequent processes of Step S208 in FIG. 3A.

In Step S210, the second insulating film 72 is formed as the front-surface-side insulating film 70. The second insulating film 72 may be formed on the upper surface of the first insulating film 71. A thickness of the second insulating film 72 may be the same as, or may be different from a thickness of the first insulating film 71. The thickness of the second insulating film 72 may be thicker than the thickness of the first insulating film 71. The second insulating film 72 may be deposited using a same manufacturing method as that of the first insulating film 71, or may be deposited using different manufacturing methods. The second insulating film 72 may be deposited under same deposition conditions as those of the first insulating film 71, or may be deposited under different deposition conditions.

The second insulating film 72 may be formed to be stacked with the first insulating film 71 inside the trench. Thereby, the first embedded insulating film 171 and the second embedded insulating film 172 are provided to be stacked in the trench part 50. In this manner, the first embedded insulating film 171 and the first non-embedded insulating film 271 may be a region where the first insulating film 71 remains. The second embedded insulating film 172 and the second non-embedded insulating film 272 may be a region where the second insulating film 72 remains. The second insulating film 72 may be formed to be stacked with the first insulating film 71 outside the trench. Thereby, the first non-embedded insulating film 271 and the second non-embedded insulating film 272 are provided to be stacked.

In Step S212, the front-surface-side electrode 110 and the back-surface-side electrode 130 are formed.

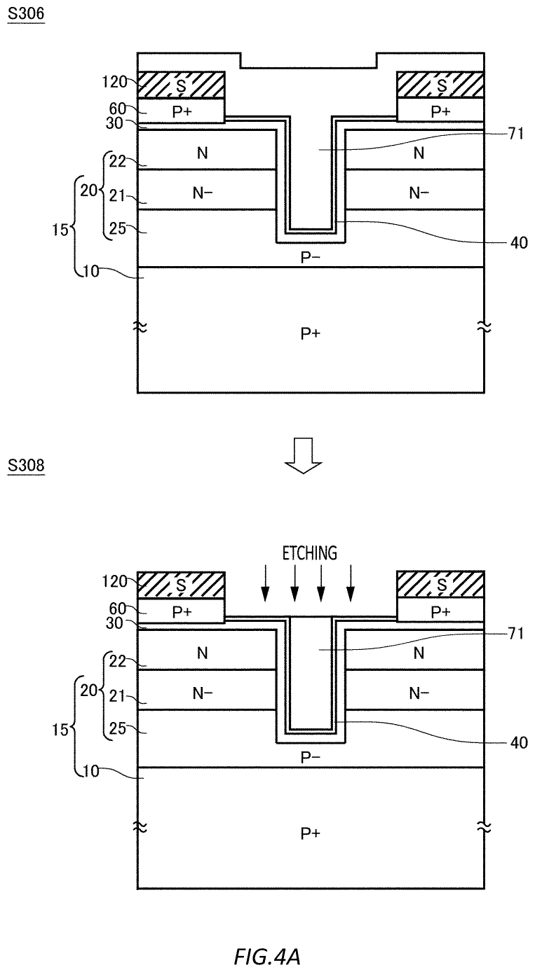

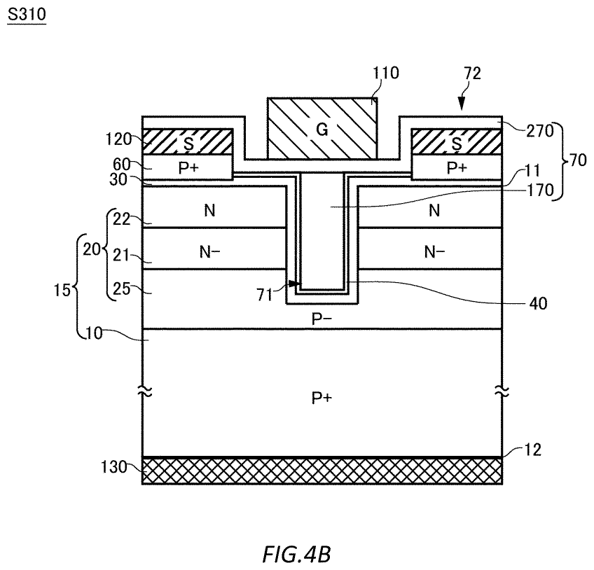

FIG. 4A illustrates an example of a method for manufacturing the diamond semiconductor device 100. In the present example, the description begins with a formation process of the first insulating film 71. Formation processes up to the termination layer 40 may be the same as those of other manufacturing methods. A method of forming the termination layer 40 of the present example is the same as the method of forming the termination layer 40 in FIG. 2B.

In Step S306, the first insulating film 71 is formed. The first insulating film 71 may be formed before forming the source electrode 120. The first insulating film 71 may be formed above both the trench part 50 and the mesa part 152. The first insulating film 71 may be formed to embed the trench entirely. The first insulating film 71 may be formed above the contact region 60 as well. After forming the first insulating film 71, an interface between the termination layer 40 and the first insulating film 71 may be improved by annealing or the like. Note that the termination layer 40 may be formed between the first insulating film 71 and the epitaxial layer 30 after forming the first insulating film 71.

In Step S308, the first insulating film 71 is etched. The first insulating film 71 outside the trench may be removed by etching. In the present example, the first insulating film 71 above both the trench part 50 and the mesa part 152 is etched. Thereby, the first insulating film 71 may be provided only inside the trench. The process for etching the first insulating film 71 may be performed by any method such as chemical etching or Chemical Mechanical Polishing (CMP). Note that the source electrode 120 may be formed after forming the first insulating film 71, or may be formed after etching the first insulating film 71.

FIG. 4B illustrates an example of a method for manufacturing the diamond semiconductor device 100. The present illustration shows the subsequent processes of Step S308 in FIG. 4A.

In Step S310, the second insulating film 72 is formed. The second insulating film 72 may be formed on the upper surface of the first insulating film 71, and may be formed on the upper surface of the source electrode 120. The second insulating film 72 of the present example is formed on the upper surface of the first insulating film 71 that has been etched. The embedded insulating part 170 may be a region where the first insulating film 71 remains. The non-embedded insulating part 270 may be a region where the second insulating film 72 remains.

The front-surface-side electrode 110 is formed on the upper surface of the second insulating film 72. The front-surface-side electrode 110 may be formed in a region where the first insulating film 71 has been etched. Thereby, a thickness of the front-surface-side insulating film 70 that exists between the front-surface-side electrode 110 and the diamond layer 15 can be adjusted.

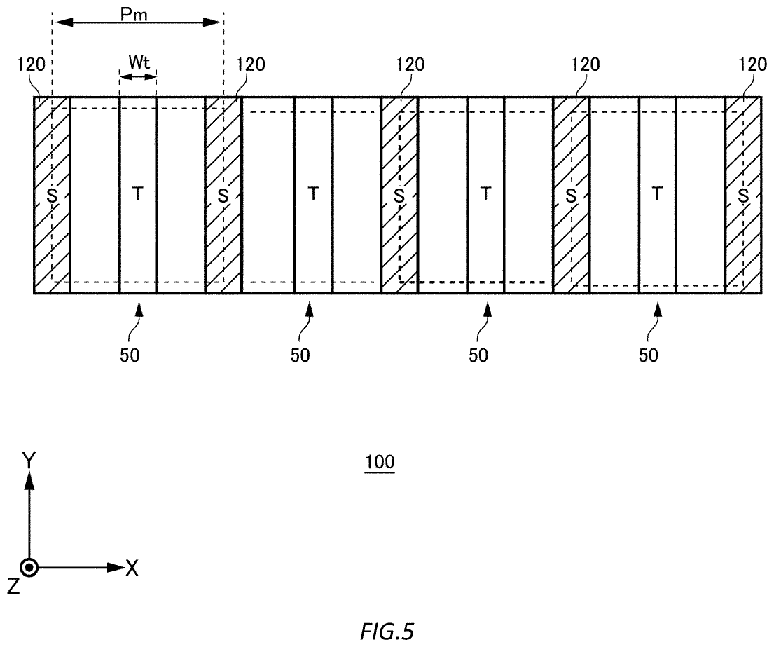

FIG. 5 illustrates an example of a top view of the diamond semiconductor device 100. The present illustration shows a top view of the diamond semiconductor device 100 that functions as a MOSFET. In the present illustration, only representative configurations, such as the trench part 50 and the source electrode 120, are illustrated, and other configurations are omitted.

The diamond semiconductor device 100 of the present example includes a plurality of trench parts 50 extending in a predetermined extending direction (Y-axis direction). Also, the diamond semiconductor device 100 of the present example includes a plurality of source electrodes 120 extending in a predetermined extending direction (Y-axis direction). That is, the trench part 50 and the source electrode 120 of the present example extend in a same direction. The plurality of source electrodes 120 may be electrically connected to a common source pad.

A pitch Pm represents a pitch of a repetition unit structure of the diamond semiconductor device 100. The diamond semiconductor device 100 of the present example has a unit structure repeated in a predetermined repetition direction (X-axis direction). The pitch Pm may be a distance from a center of the source electrode 120 to a center of an adjacent source electrode 120.

A trench width Wt may be a width of the trench part 50. That is, the trench width Wt may be a width of the front-surface-side insulating film 70 in the trench part 50. The trench width Wt may be a width of the front-surface-side insulating film 70 at an upper end of the trench part 50.

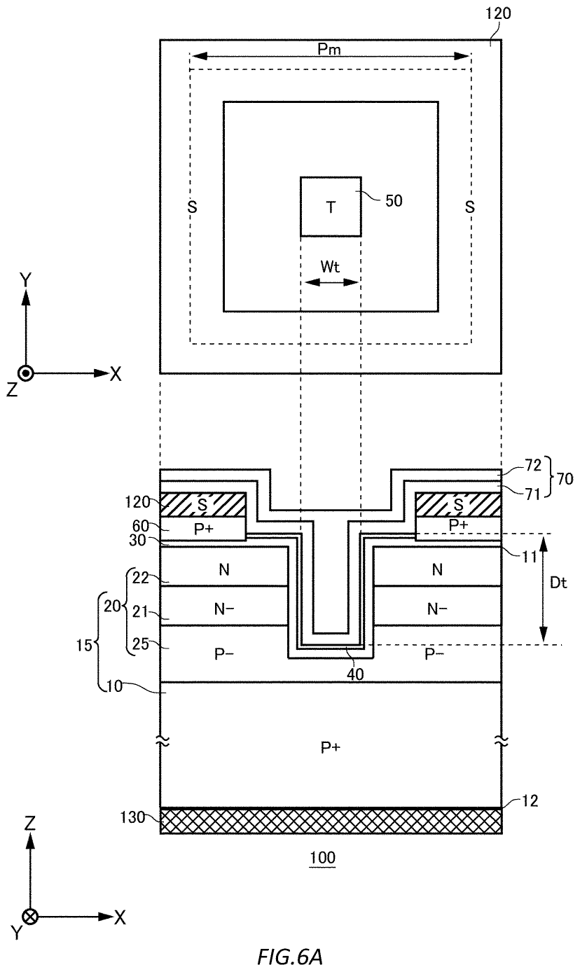

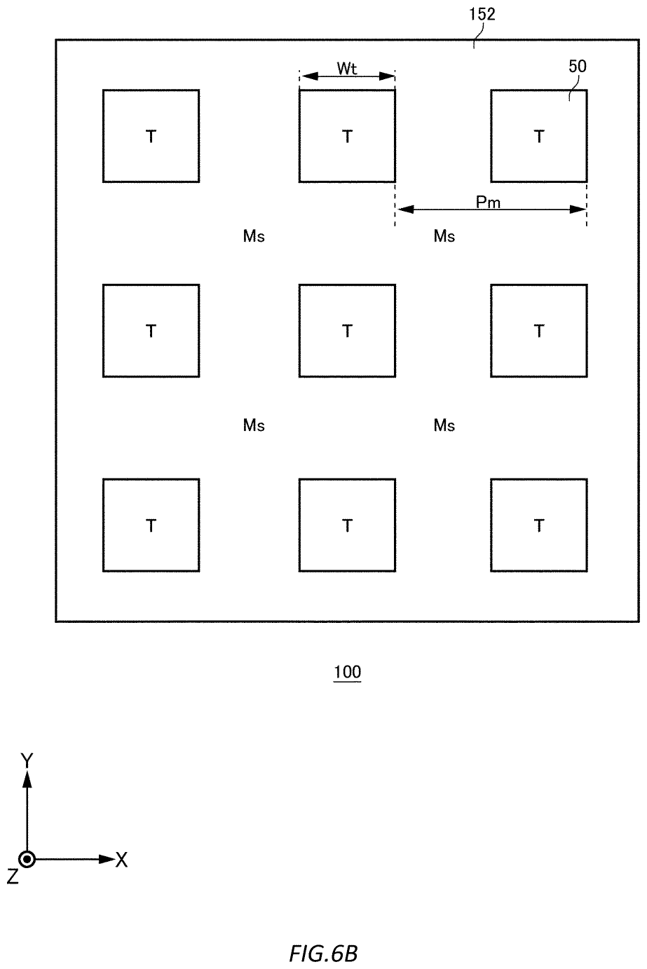

FIG. 6A illustrates an example of a top view and a cross-sectional view of the diamond semiconductor device 100. The diamond semiconductor device 100 of the present example includes the trench part 50 surrounded by the source electrode 120. In the top view, only representative configurations, such as the trench part 50 and the source electrode 120, are illustrated, and other configurations are omitted.

The source electrode 120 has a ring-shaped geometry in a top view. The source electrode 120 of the present example has a square ring. That is, in a top view, an outer circumference and an inner circumference of the source electrode 120 are both square. Note that the geometry of the source electrode 120 may be another ring-shaped geometry such as a rectangle, a polygon, a circle, or an ellipse in a top view. When the geometry of the source electrode 120 has a corner, a vertex of the corner may be rounded. For example, a polygonal source electrode 120 may be a polygon of which respective vertices are rounded.

A pitch Pm represents a pitch of a repetition unit structure of the diamond semiconductor device 100. The pitch Pm may be a distance from a center of one side of the source electrode 120 to a center of an opposing side. The pitch Pm may be 1 μm or more and 15 μm or less. The pitch Pm is 4 μm, for example. The diamond semiconductor device 100 of the present example has a same pitch Pm in the X-axis direction and the Y-axis direction, but may have different pitches Pm in the X-axis direction and the Y-axis direction.

A trench width Wt may be a width of the trench part 50 in the repetition direction. The geometry of the trench part 50 of the present example is a square with four sides of a length of the trench width Wt in a top view. The geometry of the trench part 50 may be another geometry, such as a rectangle, a polygon, a circle, or an ellipse in a top view. When the geometry of the trench part 50 has a corner, a vertex of the corner may be rounded. For example, a polygonal trench part 50 may be a polygon of which respective vertices are rounded. The trench width Wt may be 50 nm or more and 2.0 μm or less, and may be 100 nm or more and 1.5 μm or less. The trench width Wt is 500 nm, for example.

A trench depth Dt is a width in a depth direction of the trench part 50. The trench depth Dt may be a distance from an upper surface of the termination layer 40 to a lower end of the front-surface-side insulating film 70. The trench depth Dt may be 60 nm or more and 20 μm or less. The trench depth Dt may also be the same in a diamond semiconductor device 100 of another example embodiment.

FIG. 6B illustrates an example of a top view of an integrated structure of the diamond semiconductor device 100. The diamond semiconductor device 100 of the present example includes the trench part 50 surrounded by the mesa part 152. In the present illustration, only representative configurations, such as the trench part 50 and the mesa part 152, are illustrated, and other configurations are omitted. Reference sign Ms represents a region of the mesa part 152.

The diamond semiconductor device 100 of the present example includes a plurality of trench parts 50, which are repeatedly arrayed with a pitch Pm. The plurality of trench parts 50 may be arrayed at equal intervals in each of the X-axis direction and the Y-axis direction. The plurality of trench parts 50 may be arrayed diagonally at any angle. The plurality of trench parts 50 of the present example are provided periodically, but may be provided randomly with any density.

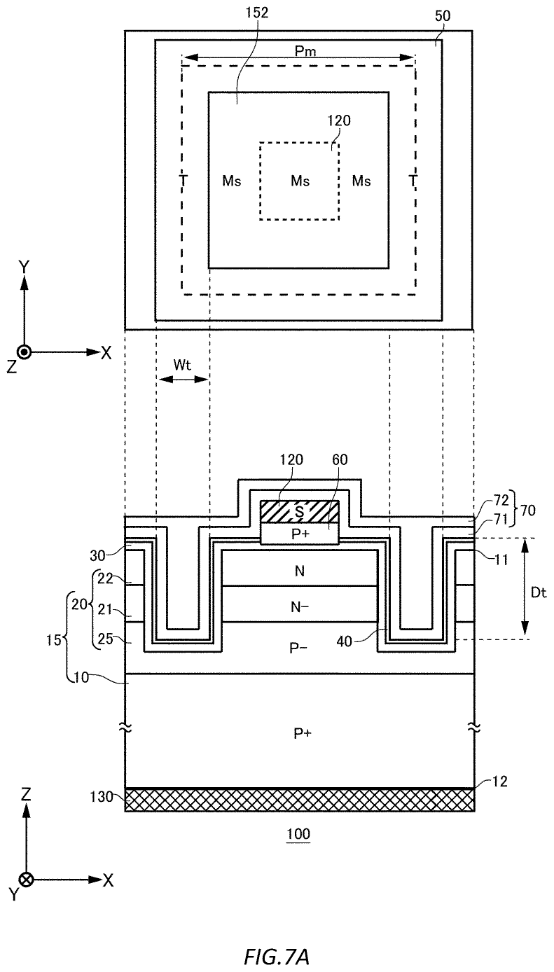

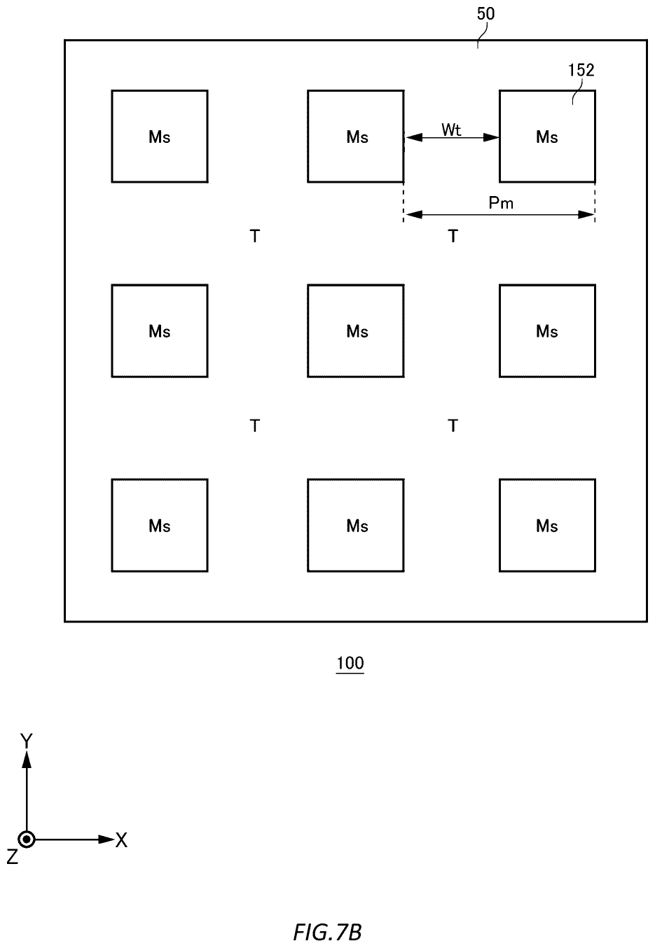

FIG. 7A illustrates an example of a top view and a cross-sectional view of the diamond semiconductor device 100. The diamond semiconductor device 100 of the present example includes the mesa part 152 surrounded by the trench part 50. In the top view, only representative configurations, such as the trench part 50, the source electrode 120, and the mesa part 152, are illustrated and other configurations are omitted.

The trench part 50 has a ring-shaped geometry in a top view. The trench part 50 of the present example has a square ring. That is, in a top view, an outer circumference and an inner circumference of the trench part 50 are both square. Note that the geometry of the trench part 50 may be another ring-shaped geometry, such as a rectangle, a polygon, a circle, or an ellipse in a top view. When the geometry of the trench part 50 has a corner, a vertex of the corner may be rounded. For example, a polygonal trench part 50 may be a polygon of which respective vertices are rounded.

A pitch Pm represents a pitch of a repetition unit structure of the diamond semiconductor device 100. The pitch Pm may be a distance from a center of one side of the trench part 50 to a center of an opposing side. The pitch Pm may be 1 μm or more and 15 μm or less. The pitch Pm is 4 μm, for example. The diamond semiconductor device 100 of the present example has a same pitch Pm in the X-axis direction and the Y-axis direction, but may have different pitches Pm in the X-axis direction and the Y-axis direction.

A trench width Wt may be a width of one side of the trench part 50. The trench width Wt may be 50 nm or more and 2.0 μm or less, and may be 100 nm or more and 1.5 μm or less. The trench width Wt is 500 nm, for example.

The geometry of the source electrode 120 of the present example is square in a top view. The geometry of the source electrode 120 may be another geometry, such as a rectangle, a polygon, a circle, or an ellipse in a top view. When the geometry of the source electrode 120 has a corner, a vertex of the corner may be rounded. For example, a polygonal source electrode 120 may be a polygon of which respective vertices are rounded.

FIG. 7B illustrates an example of a top view of an integrated structure of the diamond semiconductor device 100. The diamond semiconductor device 100 of the present example includes the mesa part 152 surrounded by the trench part 50. In the present illustration, only representative configurations, such as the trench part 50 and the mesa part 152, are illustrated, and other configurations are omitted.

The diamond semiconductor device 100 of the present example includes a plurality of mesa parts 152, which are repeatedly arrayed with a pitch Pm. The plurality of mesa parts 152 may be arrayed at equal intervals in each of the X-axis direction and the Y-axis direction. The plurality of mesa parts 152 may be arrayed diagonally at any angle. The plurality of mesa parts 152 of the present example are provided periodically, but may be provided randomly with any density.

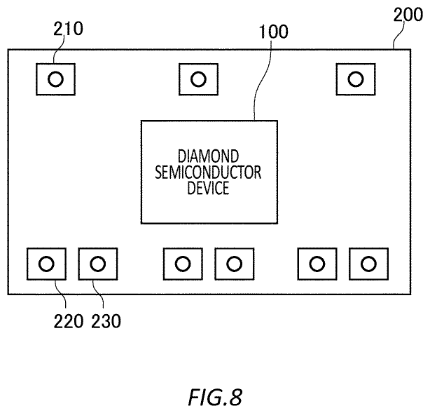

FIG. 8 illustrates an overview of a configuration of a semiconductor module 200. The semiconductor module 200 includes the diamond semiconductor device 100 that functions as a MOSFET. The semiconductor module 200 includes a gate terminal 210, a source terminal 220, and a drain terminal 230. The gate terminal 210, the source terminal 220, and the drain terminal 230 may be external connection terminals for electrically connecting with an outside of the semiconductor module 200.

The gate terminal 210 is connected with the front-surface-side electrode 110 of the diamond semiconductor device 100. The source terminal 220 is connected with the source electrode 120 of the diamond semiconductor device 100. The drain terminal 230 is connected with the back-surface-side electrode 130 of the diamond semiconductor device 100. The diamond semiconductor device 100 may be provided on an insulating substrate of the semiconductor module 200 with the back-surface-side electrode 130 facing down. The back-surface-side electrode 130 may be electrically connected with the drain terminal 230 via a metal wiring on the insulating substrate.

The semiconductor module 200 may have a single diamond semiconductor device 100, or may have a plurality of diamond semiconductor devices 100. The semiconductor module 200 may have an inverter circuit. The semiconductor module 200 may have an inverter circuit that combines the P-type channel diamond semiconductor device 100 and an N-type channel semiconductor element. The N-type channel semiconductor element may be the N-type channel diamond semiconductor device 100, or may be another semiconductor element made of GaN, SiC, or the like.

While the present invention has been described by way of the embodiments, the technical scope of the present invention is not limited to the above-described embodiments. It is apparent to persons skilled in the art that various modifications or improvements can be made to the above-described embodiments. It is also apparent from the description of the claims that the embodiments to which such modifications or improvements are made can fall within the technical scope of the present invention.

### EXPLANATION OF REFERENCES

10: diamond substrate; 11: front surface; 12: back surface; 15: diamond layer; 20: doped region; 21: first region; 22: second region; 25: doped layer; 30: epitaxial layer; 40: termination layer; 50: trench part; 60: contact region; 70: front-surface-side insulating film; 71: first insulating film; 72: second insulating film; 110: front-surface-side electrode; 120: source electrode; 130: back-surface-side electrode; 152: mesa part; 100: diamond semiconductor device; 170: embedded insulating part; 171: first embedded insulating film; 172: second embedded insulating film; 200: semiconductor module; 210: gate terminal; 220: source terminal; 230: drain terminal; 270: non-embedded insulating part; 271: first non-embedded insulating film; 272: second non-embedded insulating film.

1. A diamond semiconductor device having a trench part on a front surface, comprising:
a diamond layer;
a diamond epitaxial layer provided on the diamond layer;
a front-surface-side insulating film provided above the epitaxial layer; and
a front-surface-side electrode provided on the front-surface-side insulating film, wherein
the front-surface-side insulating film includes an embedded insulating part which is filled into an inside of the trench part to be in contact with a trench sidewall of the trench part.

2. The diamond semiconductor device according to claim 1, wherein
the front-surface-side insulating film includes a non-embedded insulating part provided above a mesa part adjacent to the trench part.

3. The diamond semiconductor device according to claim 2, wherein
a material of the embedded insulating part is the same as a material of the non-embedded insulating part.

4. The diamond semiconductor device according to claim 1, wherein
the embedded insulating part includes:
a first embedded insulating film provided to be in contact with a trench sidewall of the trench part; and
a second embedded insulating film provided to be stacked with the first embedded insulating film in the trench part.

5. The diamond semiconductor device according to claim 4, wherein
a thickness of the first embedded insulating film is thinner than that of the second embedded insulating film.

6. The diamond semiconductor device according to claim 4, wherein
a thickness of the first embedded insulating film is 10 nm or more and 100 nm or less.

7. The diamond semiconductor device according to claim 2, wherein
a material of the embedded insulating part is different from a material of the non-embedded insulating part.

8. The diamond semiconductor device according to claim 7, wherein
a dielectric constant of the embedded insulating part is lower than a dielectric constant of the non-embedded insulating part.

9. The diamond semiconductor device according to claim 2, wherein
a material of the embedded insulating part includes at least one of SiO2, SiNx, HfO2, HfSiO4, or BN, and
a material of the non-embedded insulating part includes at least one of Al2O3, SiO2, SiNx, HfO2, HfSiO4, or BN.

10. The diamond semiconductor device according to claim 2, wherein
a material of the embedded insulating part includes at least one of Al2O3, SiO2, SiNx, HfO2, HfSiO4, or BN, and
a material of the non-embedded insulating part includes at least one of SiO2, SiNx, HfO2, HfSiO4, or BN.

11. The diamond semiconductor device according to claim 2, wherein
a material of the embedded insulating part and the non-embedded insulating part is Al2O3.

12. The diamond semiconductor device according to claim 1, wherein
the front-surface-side electrode is provided to extend from above one sidewall of the trench part to above another sidewall, covering over the embedded insulating part.

13. The diamond semiconductor device according to claim 1, wherein
the front-surface-side electrode is not provided above the trench part, but is provided above a mesa part adjacent to the trench part.

14. The diamond semiconductor device according to claim 1, comprising
a source electrode provided above the diamond layer, wherein
the front-surface-side electrode is a gate electrode and is also provided above the source electrode.

15. The diamond semiconductor device according to claim 1, comprising
a termination layer provided between the epitaxial layer and the trench part.

16. The diamond semiconductor device according to claim 1, wherein
a trench width of the trench part is 100 nm or more and 1.5 μm or less, and
a trench depth of the trench part is 60 nm or more and 20 μm or less.

17. The diamond semiconductor device according to claim 1, wherein
the trench part has a taper, and
a tapering angle of the taper is 60 degrees or more and 100 degrees or less.

18. A method for manufacturing a diamond semiconductor device having a trench part on a front surface, comprising:
a step for providing a diamond layer;
a step for forming a diamond epitaxial layer on the diamond layer;
a step for forming a front-surface-side insulating film above the epitaxial layer; and
a step for forming a front-surface-side electrode on the front-surface-side insulating film, wherein
the step for forming the front-surface-side insulating film includes a step for forming an embedded insulating part which is filled into an inside of the trench part to be in contact with a trench sidewall of the trench part.

19. The method for manufacturing a diamond semiconductor device according to claim 18, wherein
the step for forming the embedded insulating part includes:
a step for forming a first embedded insulating film to be in contact with a trench sidewall of the trench part; and
a step for forming a second embedded insulating film to be stacked with the first embedded insulating film in the trench part.

20. The method for manufacturing a diamond semiconductor device according to claim 19, wherein
the step for forming the embedded insulating part includes a step for annealing the diamond semiconductor device after the step for forming the first embedded insulating film and before the step for forming the second embedded insulating film.
